(19) United States
(12) Patent Application Publication
(10) Pub. No.: US 2026/0302579 A1
(43) Pub. Date: Oct. 1, 2026

(54) RADIO FREQUENCY ADJUSTMENT STRUCTURE REDUCING INFLUENCE OF METAL DEBRIS

(71) Applicant: Suzhou Luxshare Technology Co., Ltd., Suzhou City (CN)

(72) Inventors: Wei WANG, Suzhou City (CN); Guiping GAO, Suzhou City (CN); Xinghua SUN, Suzhou City (CN)

(73) Assignee: Suzhou Luxshare Technology Co., Ltd., Suzhou City (CN)

(21) Appl. No.: 19/366,772

(22) Filed: Oct. 23, 2025

(30) Foreign Application Priority Data
Mar. 27, 2025 (CN) 202510376577.0

(51) Int. Cl. H01P 1/00

(52) U.S. Cl. CPC H01P 1/00

(57) ABSTRACT

A radio frequency adjustment structure includes an adjustable screw rod, a cover plate, and a location limiter. The adjustable screw rod includes a cap-shaped cover portion and a smooth rod portion being located at a central axis of the cap-shaped cover portion. The cap-shaped cover portion includes a first inner thread surrounding in a vertical direction. The cover plate includes a plate portion extending in a horizontal direction and a column portion extending in the vertical direction. The cover plate has a through hole penetrating through the plate portion and the column portion in the vertical direction. The smooth rod portion is inserted through the through hole. The column portion includes a first outer thread spirally surrounding in the vertical direction. The first inner thread is engaged with the first outer thread. The location limiter is sleeved around the column portion and abutted below the cap-shaped cover portion.

### CROSS-REFERENCE TO RELATED APPLICATION

This patent application claims priority of a Chinese Patent Application No. 202510376577.0, filed on Mar. 27, 2025 and titled “RADIO FREQUENCY ADJUSTMENT STRUCTURE”, the entire content of which is incorporated herein by reference.

### TECHNICAL FIELD

The present disclosure relates to a field of radio frequency, particularly to a radio frequency adjustment structure reducing influence of metal debris.

### BACKGROUND

In an existing radio frequency (RF) adjustment structure in a RF field, a screw and a nut are designed separately. The nut includes an inner thread, and the screw includes an outer thread. The screw is inserted into a cover plate and suspended installed on the cover plate through a mutual engagement of the inner and outer threads. The frequency is adjusted by varying a depth to which the screw extends below the cover plate. However, since the cover plate includes a through hole for the screw to pass through, when the screw and the nut are designed separately and the nut includes an inner thread while the screw includes an outer thread, the debris generated by the spiral engagement of the inner and outer threads can easily fall into the frequency adjustment cavity below the cover plate through the through hole. In the existing common RF adjustment structure, the debris accumulated in the frequency adjustment cavity over a long period of time will affect the frequency adjustment effect of the RF adjustment structure. Therefore, a RF adjustment structure that can prevent debris from falling into the frequency adjustment cavity is needed. However, in the structure mentioned above, the screw needs to be tightly attached to the top surface of the cover plate after being rotated downward. In the actual debugging process, the screw needs to be repeatedly rotated up and down, and the debugging depth will be adjusted up and down according to the actual situation. The specific stopping position cannot be quantified or specified. The debugging and tightening function is relatively single and cannot achieve the purpose of "locking and stopping immediately". It can only be locked when the screw is tightly attached to the top surface of the cover plate. In actual use, it cannot meet the various needs in production and has poor stability.

### SUMMARY

An embodiment of the present disclosure adopts the following technical solution: a radio frequency adjustment structure, including: an adjustable screw rod including a cap-shaped cover portion and a smooth rod portion located at a central axis of the cap-shaped cover portion, the smooth rod portion defining a vertical direction, the cap-shaped cover portion including a first inner thread spirally surrounding in the vertical direction; a cover plate including a plate portion extending in a horizontal direction and a column portion extending in the vertical direction, the cover plate having a through hole penetrating through the plate portion and the column portion in the vertical direction, the smooth rod portion being inserted through the through hole, the column portion including a first outer thread spirally surrounding in the vertical direction, and the first inner thread being spirally engaged with the first outer thread; a box base being located below the plate portion, a frequency adjustment cavity being formed between the plate portion and the box base, the smooth rod portion partly extending into the frequency adjustment cavity, the cap-shaped cover portion being located above the plate portion and surrounding the column portion; and a location limiter being sleeved around the column portion, the location limiter being located below the cap-shaped cover portion, an abutment being formed between the location limiter and the cap-shaped cover portion along the vertical direction.

An embodiment of the present disclosure adopts the following technical solution: a radio frequency adjustment structure, including: an adjustable screw rod including a cap-shaped cover portion and a smooth rod portion located at a central axis of the cap-shaped cover portion, the smooth rod portion defining a vertical direction, the cap-shaped cover portion including a first inner thread spirally surrounding in the vertical direction; a cover plate including a plate portion extending in a horizontal direction and a column portion extending in the vertical direction, the cover plate having a through hole penetrating through the plate portion and the column portion in the vertical direction, the smooth rod portion being inserted through the through hole, the column portion including a first outer thread spirally surrounding in the vertical direction, and the first inner thread being spirally engaged with the first outer thread; and a location limiter being sleeved around the column portion, the location limiter being located below the cap-shaped cover portion, an abutment being formed between the location limiter and the cap-shaped cover portion along the vertical direction.

An embodiment of the present disclosure adopts the following technical solution: a radio frequency adjustment structure, including: an adjustable screw rod including a cap-shaped cover portion and a smooth rod portion located at a central axis of the cap-shaped cover portion, the smooth rod portion defining a vertical direction, the cap-shaped cover portion including a first inner thread spirally surrounding in the vertical direction; a cover plate including a plate portion extending in a horizontal direction and a column portion extending in the vertical direction, the cover plate having a through hole penetrating through the plate portion and the column portion in the vertical direction, the smooth rod portion being inserted through the through hole, the column portion including a first outer thread spirally surrounding in the vertical direction, and the first inner thread being spirally engaged with the first outer thread; and a location limiter being sleeved around the column portion, the location limiter being abutted below the cap-shaped cover portion.

### BRIEF DESCRIPTION OF DRAWINGS

FIG. 1 is a perspective, assembled view of a radio frequency (RF) adjustment structure in accordance with of the present disclosure;

FIG. 2 is a perspective, partly assembled view of the RF adjustment structure in accordance with a first embodiment of the present disclosure;

FIG. 3 is a top view of a part of the RF adjustment structure, which is shown in FIG. 2 of the first embodiment;

FIG. 4 is a cross-sectional view taken along line A-A in FIG. 3 of the RF adjustment structure in the assembled state of the first embodiment;

FIG. 5 is a perspective, partly exploded view of the RF adjustment structure in accordance with the first embodiment of the present disclosure;

FIG. 6 is a cross-sectional view taken along line A-A in FIG. 3 of the RF adjustment structure in the exploded state of the first embodiment;

FIG. 7 is a perspective, partly assembled view of the RF adjustment structure in accordance with a second embodiment of the present disclosure;

FIG. 8 is a top view of a part of the RF adjustment structure, which is shown in FIG. 7 of the second embodiment;

FIG. 9 is a cross-sectional view taken along line B-B in FIG. 8 of the RF adjustment structure in the assembled state of the second embodiment;

FIG. 10 is a perspective, partly exploded view of the RF adjustment structure in accordance with the second embodiment of the present disclosure;

FIG. 11 is a cross-sectional view along line B-B in FIG. 8 of the second embodiment of the RF adjustment structure in the disassembled state;

FIG. 12 is a perspective, partly assembled view of the RF adjustment structure in accordance with a third embodiment of the present disclosure;

FIG. 13 is a top view of a part of the RF adjustment structure, which is shown in FIG. 12 of the third embodiment;

FIG. 14 is a cross-sectional view taken along line C-C in FIG. 13 of the RF adjustment structure in the assembled state of the third embodiment;

FIG. 15 is a perspective, partly exploded view of the RF adjustment structure in accordance with the third embodiment of the present disclosure;

FIG. 16 is a cross-sectional view along line C-C in FIG. 13 of the third embodiment of the RF adjustment structure in the disassembled state;

FIG. 17 is a perspective, partly assembled view of the RF adjustment structure in accordance with a fourth embodiment of the present disclosure;

FIG. 18 is a perspective, partly exploded view of the RF adjustment structure in accordance with the fourth embodiment of the present disclosure;

FIG. 19 is another perspective view of an elastic piece of the RF adjustment structure in the fourth embodiment from another angle;

FIG. 20 is a front view of a partly assembled state of the fourth embodiment of the RF adjustment structure;

FIG. 21 is a front view of the partly exploded state of the fourth embodiment of the RF adjustment structure;

FIG. 22 is a perspective, partly assembled view of the RF adjustment structure in accordance with a fifth embodiment of the present disclosure, in which half of a cover plate is sectioned;

FIG. 23 is a perspective, partly exploded view of the RF adjustment structure in accordance with the fifth embodiment of the present disclosure, which is shown in FIG. 22;

FIG. 24 is a cross-sectional view of the partly assembled state of the fifth embodiment of the RF adjustment structure; and

FIG. 25 is a cross-sectional view of the partly exploded state of the fifth embodiment of the RF adjustment structure.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

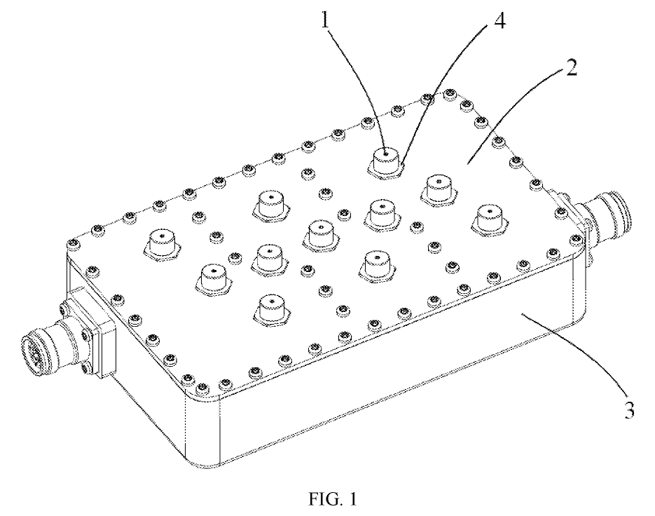

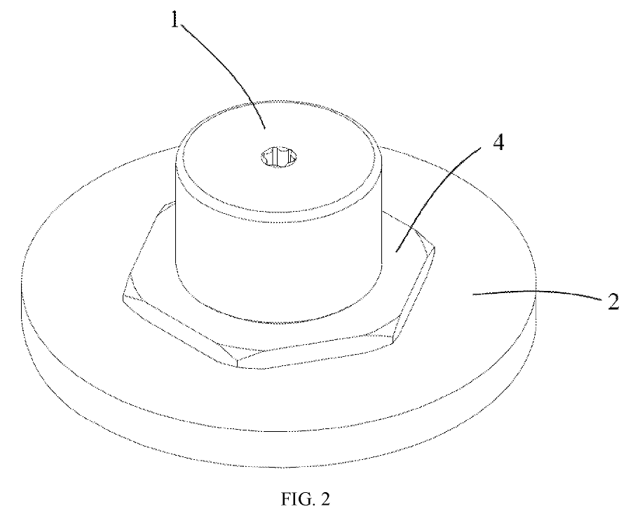

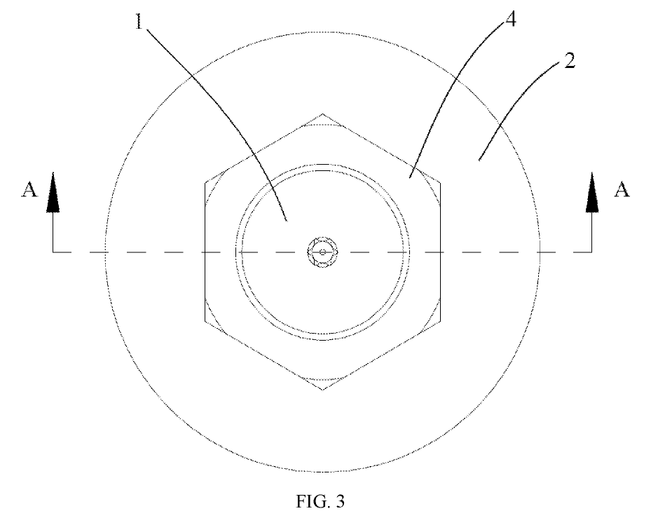

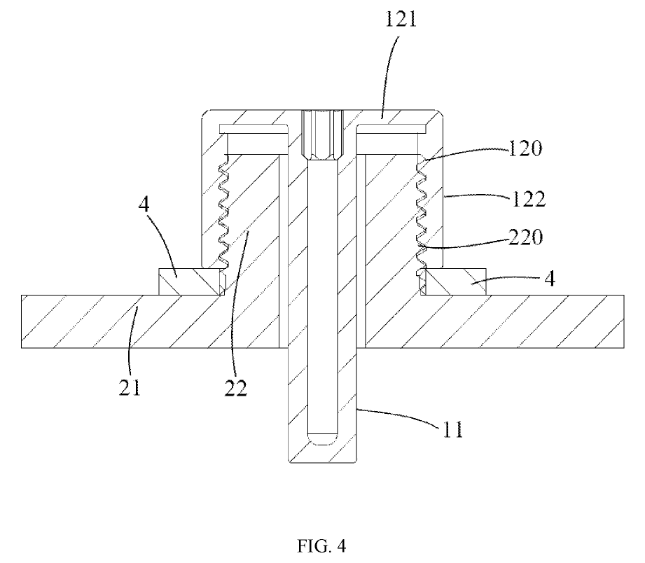

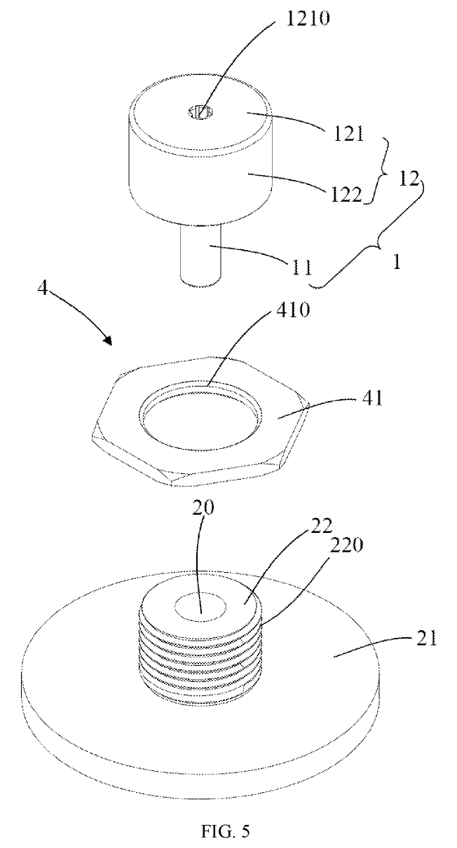

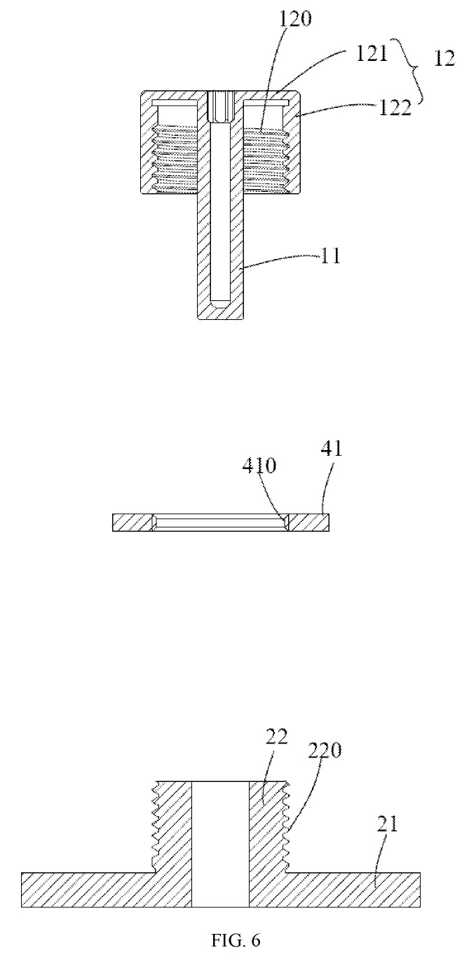

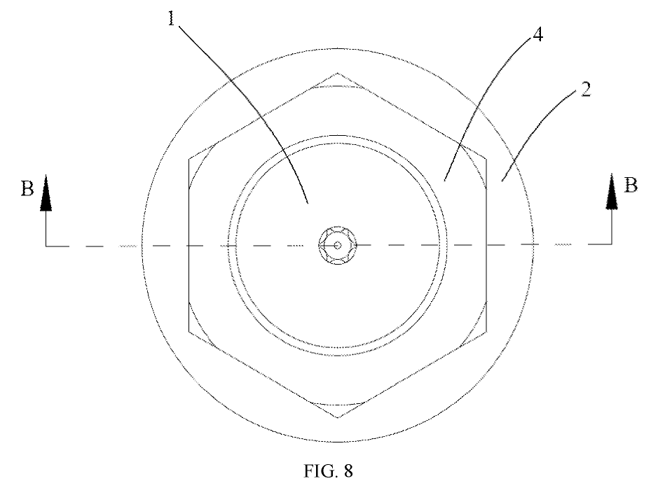

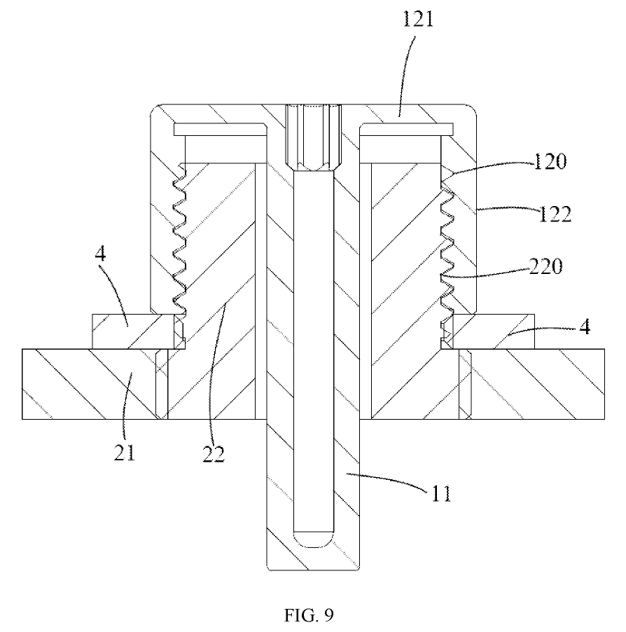

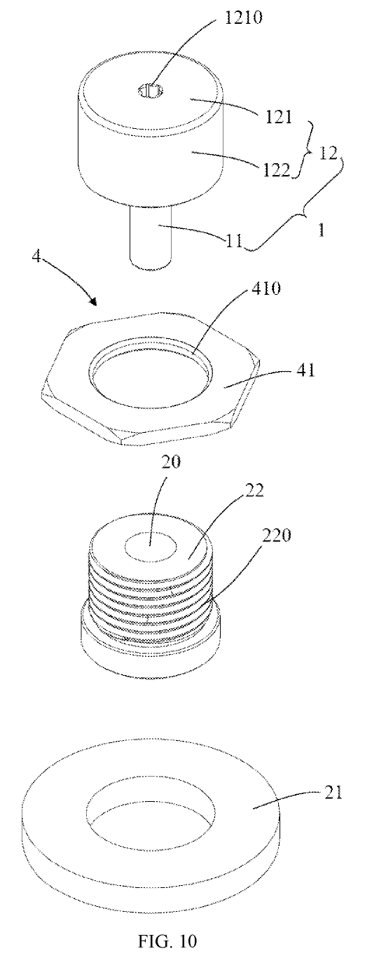

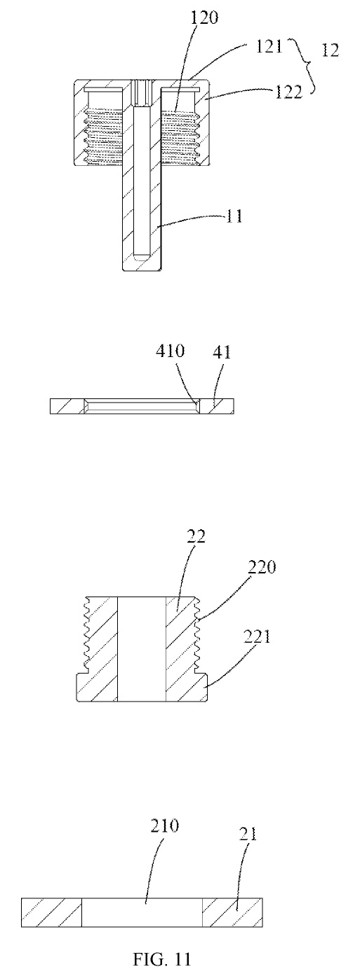

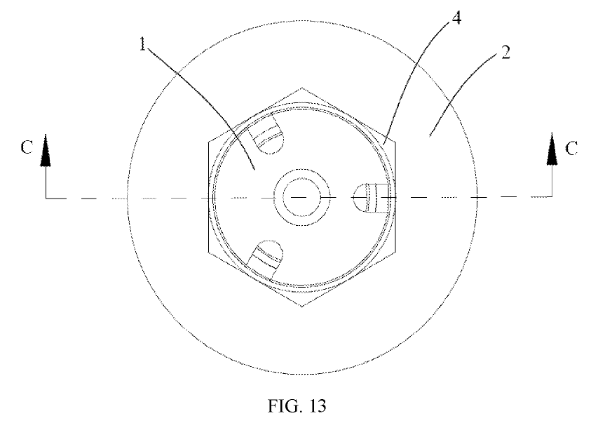

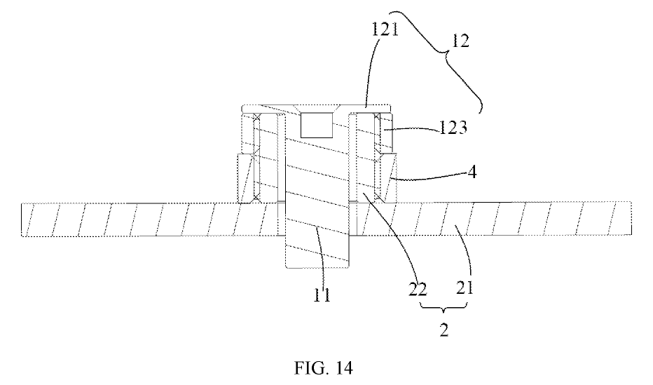

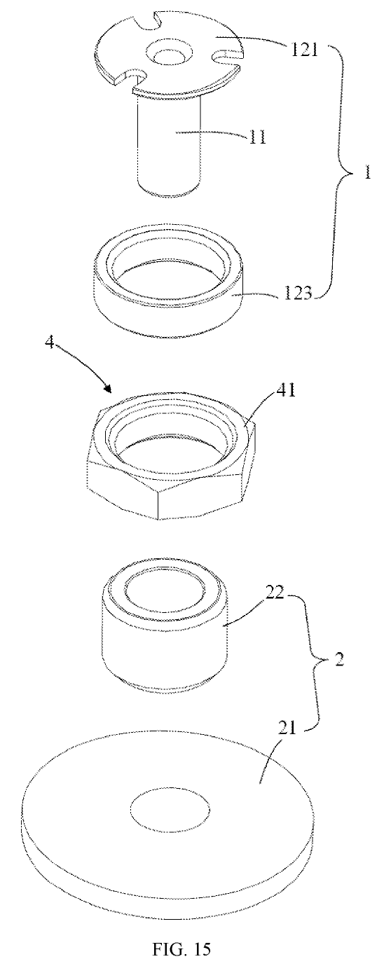

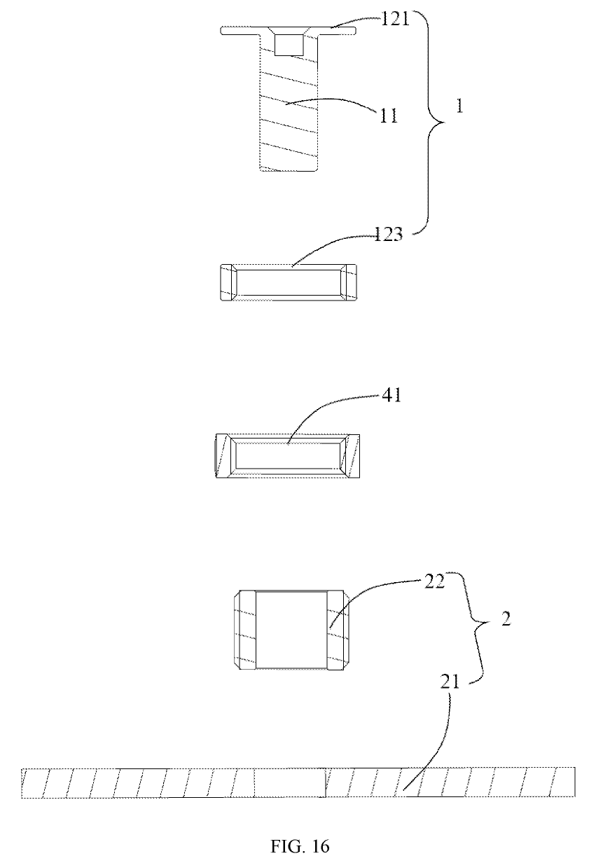

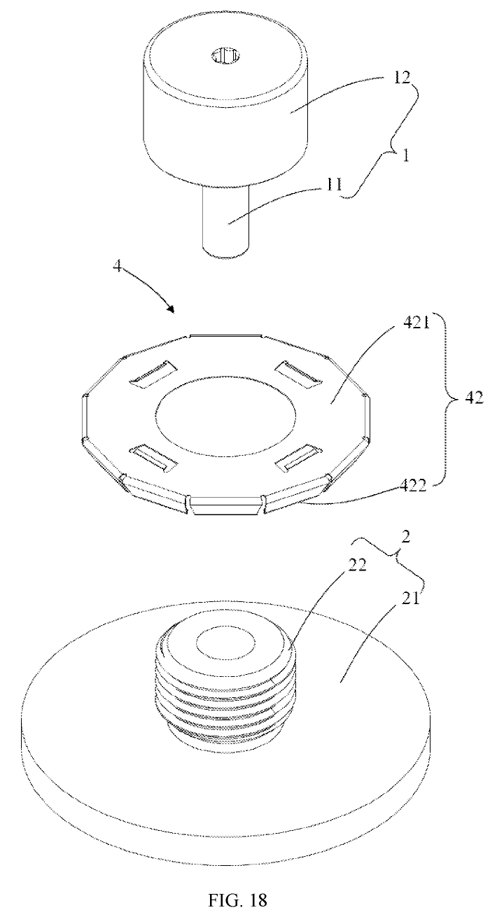

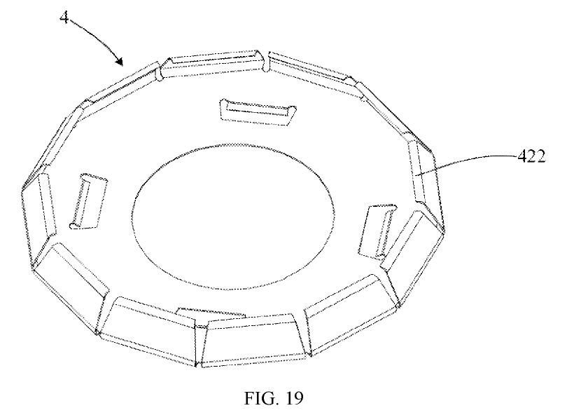

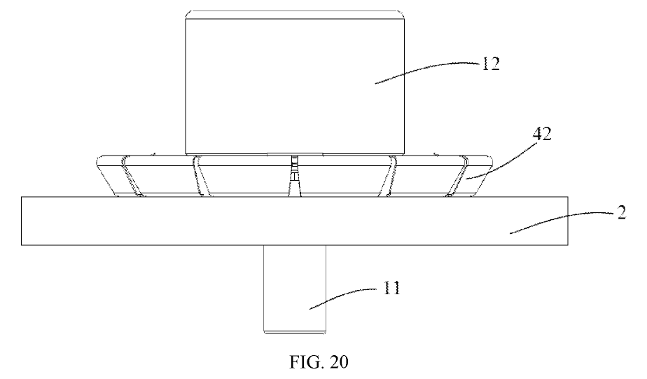

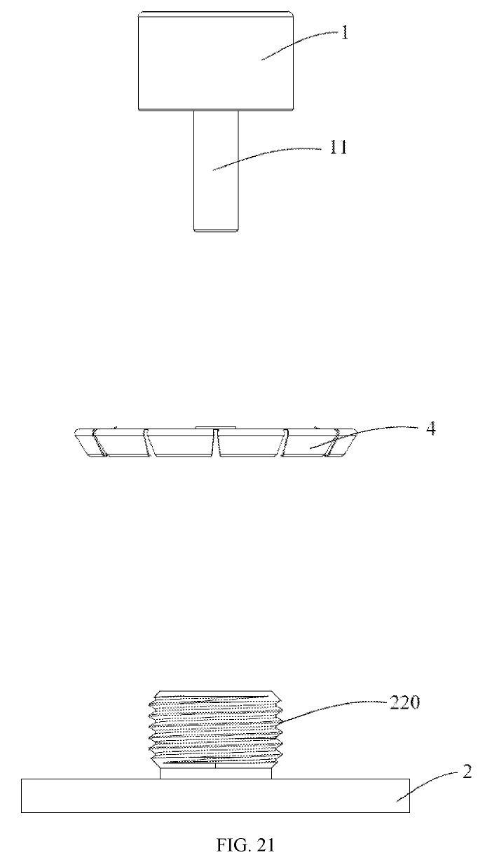

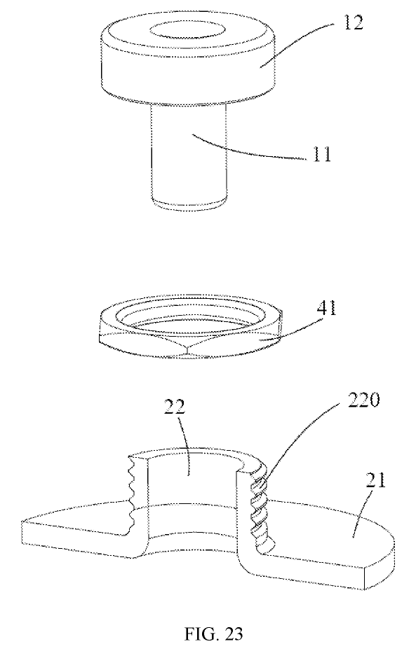

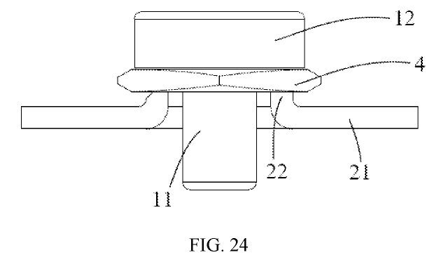

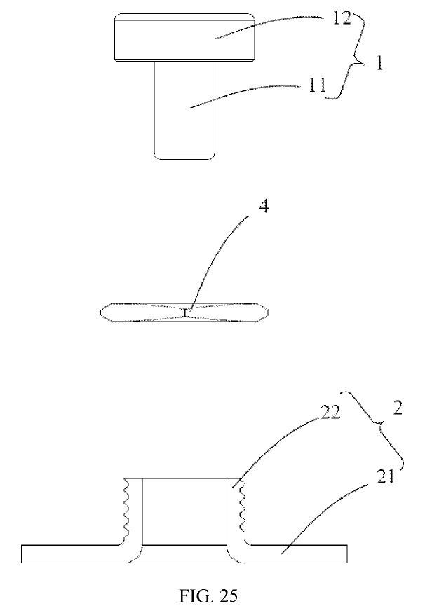

Referring to FIGS. 1 to 25, the present disclosure discloses a radio frequency (RF) adjustment structure, including: an adjustable screw rod 1, a cover plate 2 and a location limiter 4. The adjustable screw rod 1 includes a cap-shaped cover portion 12 and a smooth rod portion 11 located at a central axis of the cap-shaped cover portion 12. The smooth rod portion 11 defines a vertical direction, and the cap-shaped cover portion 12 includes a first inner thread 120 spirally surrounding in the vertical direction. The cover plate 2 includes a plate portion 21 extending in a horizontal direction and a column portion 22 extending in a vertical direction. The cover plate 2 has a through hole 20, which penetrates through the column portion 22 and the plate portion 21 in the vertical direction from top to bottom. The smooth rod portion 11 is inserted through the through hole 20, specifically, the smooth rod portion 11 is inserted through the through hole 20 from the side of the column portion 22 away from the plate portion 21 and extends out of the side of the plate portion 21 away from the column portion 22. The column portion 22 includes a first outer thread 220 spirally surrounding in the vertical direction, and the first inner thread 120 is spirally engaged with the first outer thread 220. A box base 3 is located below the plate portion 21, and a frequency adjustment cavity is formed between the plate portion 21 and the box base 3. The smooth rod portion 11 partly extends into the frequency adjustment cavity. The cap-shaped cover portion 12 is located above the plate portion 21 and surrounds the column portion 22. The location limiter 4 is sleeved around the column portion 22, the location limiter 4 is located below the cap-shaped cover portion 12, and an upper and lower abutment is formed between the location limiter 4 and the cap-shaped cover portion 12.

The RF adjustment structure of the present disclosure mainly lies in the setting of the location limiter 4, which can provide a limit force between the adjustable screw rod 1 and the cover plate 2. Therefore, the RF adjustment structure not only can avoid debris from falling into the frequency adjustment cavity below the cover plate 2 by the helical engagement between the first inner thread 120 of the cap-shaped cover portion 12 and the first outer thread 220 of the column portion 22, improving the intermodulation and optimizing the frequency adjustment effect; but also can further limit an installation depth of the adjustable screw rod 1 relative to the cover plate 2 in the frequency adjustment cavity through the cooperation among the adjustable screw rod 1, the cover plate 2 and the location limiter 4, thus achieving "lock and stop immediately", ensuring the stability of the adjustable screw rod 1 during the debugging process.

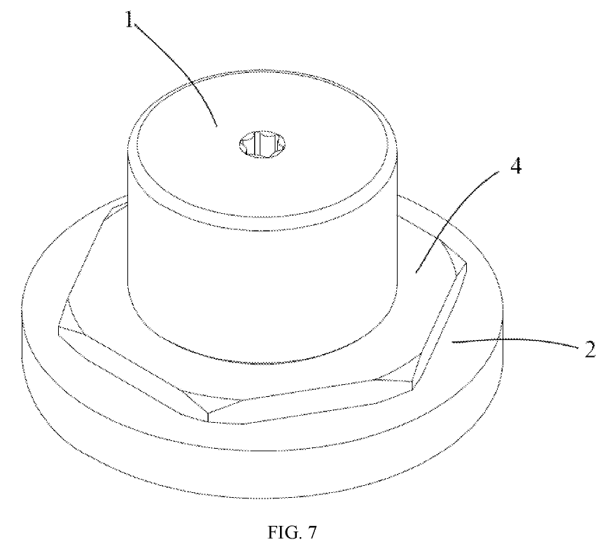

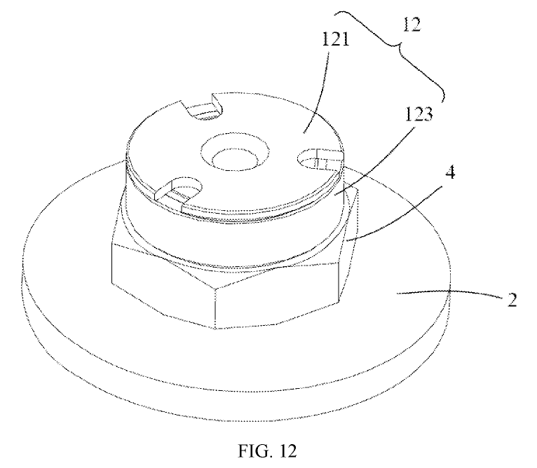

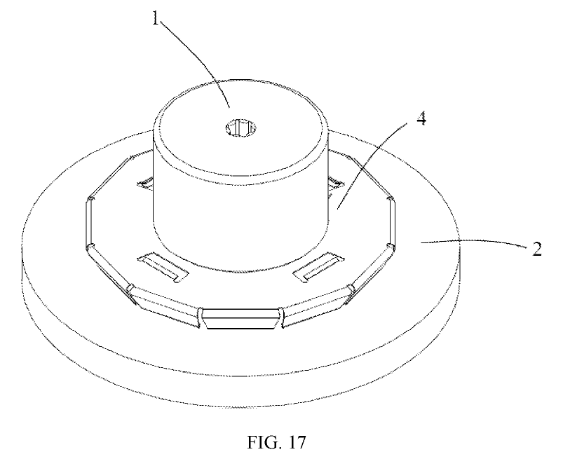

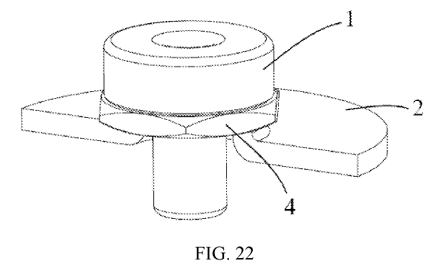

Referring to a first embodiment shown in FIGS. 1 to 6, a second embodiment shown in FIGS. 7 to 11, a fourth embodiment shown in FIGS. 17 to 21 and a fifth embodiment shown in FIGS. 22 to 25, the cap-shaped cover portion 12 includes a horizontally-extending top plate 121 and a vertically-extending annular side plate 122. The top plate 121 defines a slot opening 1210 for facilitating the positioning and tightening by tools. Referring to a third embodiment shown in FIGS. 12 to 16, although it does not include the annular side plate 122 extending vertically from the top plate 121 as the above-mentioned four embodiments (the first, second, fourth, and fifth embodiments), but it includes an annular spacer block 123, which is separately arranged from the top plate 121 and also functions as the annular side plate 122 after being welded to the top plate 121.

Following is a detailed description of two specific implementation methods of the location limiter 4.

Referring to FIGS. 1 to 16 and 22 to 25, a first embodiment of the location limiter 4 is a screw nut 41. The screw nut 41 includes a second inner thread 410, which is spirally engaged with the first outer thread 220 below the first inner thread 120. A top edge of the screw nut 41 is configured in continuous contact with a bottom edge of the cap-shaped cover portion 12 while a bottom edge of the screw nut 41 is configured in separable contact with a top edge of the plate portion 21. That is, the spiral engagement between the second inner thread 410 of the screw nut 41 and the first outer thread 220 of the column portion 22 suspends the screw nut 41 at a certain position on the column portion 22, or uses the thickness of the screw nut 41 to limit the installation depth of the adjustable screw rod 1 relative to the cover plate 2, and further controls a depth to which the smooth rod portion 11 extends into the frequency adjustment cavity.

Referring to FIGS. 17 to 21, a second embodiment of the location limiter 4 is an elastic piece 42. The elastic piece 42 has an upper end 421 and a lower end 422 that are oppositely arranged. The upper end 421 of the elastic piece 42 is configured in continuous contact with the bottom edge of the cap-shaped cover portion 12, and the lower end 422 of the elastic piece 42 is configured in continuous contact with the top edge of the plate portion 21. The continuous contact between the upper end 421 of the elastic piece 42 and the cap-shaped cover portion 12 and the continuous contact between the lower end 422 of the elastic piece 42 and the plate portion 21 enable the elastic piece 42 to be compressed. By utilizing the elastic deformation of the elastic piece 42, the installation depth of the adjustable screw rod 1 relative to the cover plate 2 can be restricted, and further control a depth to which the smooth rod portion 11 extends into the frequency adjustment cavity.

Therefore, the present disclosure provides two specific embodiments of the location limiter 4. That is, the location limiter 4 can be either the screw nut 41 or the elastic piece 42. Each of the two specific embodiments of the location limiter 4 has its own advantages and disadvantages. The advantage of the screw nut 41 is that it has a stable structure and a long service life; the disadvantage of the screw nut 41 is that its position adjustment needs to be done manually to limit a position of the adjustable screw rod 1, which is rather cumbersome. The advantage of the elastic piece 42 is that it can self-adjust its thickness to limit the position of the adjustable screw rod 1, which is relatively simple; the disadvantage is that it is prone to elastic fatigue and has a short service life. The elastic piece 42 is not limited to the specific form of a spring sheet. In other embodiments which are not shown, the location limiter 4 can also be a gasket having elastic. Since the gasket does not have an inner thread like the screw nut 41, it is more similar to the elastic piece 42 and limits the installation depth of the adjustable screw rod 1 relative to the cover plate 2 through its elastic deformation.

Following is a detailed description of various specific implementation methods of the adjustable screw rod 1 and/or the cover plate 2.

Referring to FIGS. 1 to 6, the cover plate 2 is an integral piece with one part (the column portion 22) protruding upward from the other part (the plate portion 21). Referring to FIGS. 22 to 25, the cover plate 2 is an integral piece with one part (the column portion 22) stretched upward from the other part (the plate portion 21) and therefore, the cover plate 2 is an integral piece coming from a stretching molding. In the two above-mentioned conditions, although forming processes of the cover plate 2 are different, the column portion 22 and the plate portion 21 are always an integral structure.

Of course, it is easy to think that the column portion 22 and the plate portion 21 can also be a separable structure.

Referring to FIGS. 7 to 11, the column portion 22 and the plate portion 21 are arranged in a first embodiment of the separate structure, where the column portion 22 includes a base portion 221 being located below the location limiter 4. The plate portion 21 includes a receiving cavity 210 accommodating the base portion 221. The base portion 221 and the plate portion 21 are coupled to each other by either a threaded connection or a riveting connection. When the base portion 221 and the plate portion 21 are coupled to each other by a threaded connection, it can be understood that the outer surface of the base portion 221 includes a second outer thread (not shown), and the inner wall facing the receiving cavity 210 of the plate portion 21 includes a third inner thread (not shown). The second outer thread and the third inner thread cooperate to threaded connect the base portion 221 to the plate portion 21. When the base portion 221 and the plate portion 21 are coupled to each other by a riveting connection, the base portion 221 can be directly riveted to the plate portion 21 by a riveting method. The diameter of the cross-sectional area of the base portion 221 is greater than the diameter of the cross-sectional area of the column portion 22 where the first outer thread 220 is located.

Referring to FIGS. 12 to 16, the column portion 22 and the plate portion 21 are arranged in a second embodiment of the separate structure, where the column portion 22 is welded to the upper surface of the plate portion 21. On the basis of the second embodiment where the column portion 22 is welded to the upper surface of the plate portion 21, the adjustable screw rod 1 can also be a separate structure. Specifically, the cap-shaped cover portion 12 includes a top plate 121 and an annular spacer block 123 that are separately arranged. The annular spacer block 123 is sleeved on the column portion 22 and then the annular spacer block 123 is welded to the top plate 121. At this moment, the location limiter 4 adopts the screw nut 41, and the top edge of the screw nut 41 and a bottom edge of the annular spacer block 123 are in upper and lower abutment.

Therefore, the present disclosure firstly and mainly aims at to provide two implementation modes of the integral structure and the separate structure of the cover plate 2. Moreover, in the implementation mode of the separate structure of the cover plate 2, the replaceable implementation mode of the adjustable screw rod 1 is also provided. The integral structure and/or the separate structure of the adjustable screw rod 1 and/or the cover plate 2 are not limited to the above-mentioned ones.

In summary, the key point of the RF adjustment structure of the present disclosure lies in: the RF adjustment structure includes a location limiter 4, which can limit between the adjustable screw rod 1 and the cover plate 2. Therefore, the RF adjustment structure of the present disclosure not only can avoid debris from falling into the frequency adjustment cavity below the cover plate 2 by the screw fit between the first inner thread 120 of the cap-shaped cover portion 12 and the first outer thread 220 of the column portion 22, improving the intermodulation and optimizing the frequency adjustment effect; but also can further limit the installation depth of the adjustable screw rod 1 relative to the cover plate 2 through the cooperation among the adjustable screw rod 1, the cover plate 2 and the location limiter 4, thus achieving "lock and stop immediately", ensuring the stability of the adjustable screw rod 1 during the debugging process.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A radio frequency adjustment structure, comprising:
an adjustable screw rod comprising a cap-shaped cover portion and a smooth rod portion located at a central axis of the cap-shaped cover portion, the smooth rod portion defining a vertical direction, the cap-shaped cover portion comprising a first inner thread spirally surrounding in the vertical direction;
a cover plate comprising a plate portion extending in a horizontal direction and a column portion extending in the vertical direction, the cover plate having a through hole penetrating through the plate portion and the column portion in the vertical direction, the smooth rod portion being inserted through the through hole, the column portion comprising a first outer thread spirally surrounding in the vertical direction, and the first inner thread being spirally engaged with the first outer thread;
a box base being located below the plate portion, a frequency adjustment cavity being formed between the plate portion and the box base, the smooth rod portion partly extending into the frequency adjustment cavity, the cap-shaped cover portion being located above the plate portion and surrounding the column portion; and
a location limiter being sleeved around the column portion, the location limiter being located below the cap-shaped cover portion, an abutment being formed between the location limiter and the cap-shaped cover portion along the vertical direction.

2. The radio frequency adjustment structure according to claim 1, wherein the location limiter adopts either a screw nut or an elastic piece.

3. The radio frequency adjustment structure according to claim 2, wherein the screw nut comprises a second inner thread being spirally engagement with the first outer thread below the first inner thread, a top edge of the screw nut is configured in continuous contact with a bottom edge of the cap-shaped cover portion, and a bottom edge of the screw nut is configured in separable contact with a top edge of the plate portion.

4. The radio frequency adjustment structure according to claim 2, wherein the elastic piece has an upper end and a lower end that are oppositely arranged, the upper end of the elastic piece is configured in continuous contact with the bottom edge of the cap-shaped cover portion, and the lower end of the elastic piece is configured in continuous contact with the top edge of the plate portion.

5. The radio frequency adjustment structure according to claim 1, wherein the column portion and the plate portion adopts either an integral structure or a separable structure.

6. The radio frequency adjustment structure according to claim 5, wherein the cover plate is an integral piece coming from a stretching molding.

7. The radio frequency adjustment structure according to claim 5, wherein the column portion and the plate portion are arranged in the separate structure, in which the column portion is welded to the upper surface of the plate portion.

8. The radio frequency adjustment structure according to claim 7, wherein the cap-shaped cover portion comprises a top plate and an annular spacer block that are separately arranged, the annular spacer block is sleeved on the column portion and is welded to the top plate, the location limiter adopts the screw nut, and the top edge of the screw nut and a bottom edge of the annular spacer block are in upper and lower abutment.

9. The radio frequency adjustment structure according to claim 5, wherein the column portion and the plate portion are arranged in the separate structure, the column portion comprises a base portion being located below the location limiter and the plate portion defines a receiving cavity accommodating the base portion; and wherein
the base portion and the plate portion are coupled to each other by either a threaded connection or a riveting connection.

10. The radio frequency adjustment structure according to claim 9, wherein a diameter of the cross-sectional area of the base portion is greater than a diameter of the cross-sectional area of the column portion where the first outer thread is located.

11. A radio frequency adjustment structure, comprising:
an adjustable screw rod comprising a cap-shaped cover portion and a smooth rod portion located at a central axis of the cap-shaped cover portion, the smooth rod portion defining a vertical direction, the cap-shaped cover portion comprising a first inner thread spirally surrounding in the vertical direction;
a cover plate comprising a plate portion extending in a horizontal direction and a column portion extending in the vertical direction, the cover plate having a through hole penetrating through the plate portion and the column portion in the vertical direction, the smooth rod portion being inserted through the through hole, the column portion comprising a first outer thread spirally surrounding in the vertical direction, and the first inner thread being spirally engaged with the first outer thread; and
a location limiter being sleeved around the column portion, the location limiter being located below the cap-shaped cover portion, an abutment being formed between the location limiter and the cap-shaped cover portion along the vertical direction.

12. The radio frequency adjustment structure according to claim 11, further comprising a box base being located below the plate portion, wherein a frequency adjustment cavity is formed between the plate portion and the box base, the smooth rod portion partly extends into the frequency adjustment cavity, and the cap-shaped cover portion is located above the plate portion and surrounding the column portion.

13. The radio frequency adjustment structure according to claim 11, wherein the location limiter adopts either a screw nut or an elastic piece.

14. The radio frequency adjustment structure according to claim 13, wherein the screw nut comprises a second inner thread being spirally engagement with the first outer thread below the first inner thread, a top edge of the screw nut is configured in continuous contact with a bottom edge of the cap-shaped cover portion, and a bottom edge of the screw nut is configured in separable contact with a top edge of the plate portion.

15. The radio frequency adjustment structure according to claim 13, wherein the elastic piece has an upper end and a lower end that are oppositely arranged, the upper end of the elastic piece is configured in continuous contact with the bottom edge of the cap-shaped cover portion, and the lower end of the elastic piece is configured in continuous contact with the top edge of the plate portion.

16. The radio frequency adjustment structure according to claim 11, wherein the column portion and the plate portion adopts either an integral structure or a separable structure.

17. The radio frequency adjustment structure according to claim 16, wherein the cover plate is an integral piece coming from a stretching molding.

18. The radio frequency adjustment structure according to claim 5, wherein the column portion and the plate portion are arranged in the separate structure, in which the column portion is welded to the upper surface of the plate portion; and wherein
the cap-shaped cover portion comprises a top plate and an annular spacer block that are separately arranged, the annular spacer block is sleeved on the column portion and is welded to the top plate, the location limiter adopts the screw nut, and the top edge of the screw nut and a bottom edge of the annular spacer block are in upper and lower abutment.

19. A radio frequency adjustment structure, comprising:
an adjustable screw rod comprising a cap-shaped cover portion and a smooth rod portion located at a central axis of the cap-shaped cover portion, the smooth rod portion defining a vertical direction, the cap-shaped cover portion comprising a first inner thread spirally surrounding in the vertical direction;
a cover plate comprising a plate portion extending in a horizontal direction and a column portion extending in the vertical direction, the cover plate having a through hole penetrating through the plate portion and the column portion in the vertical direction, the smooth rod portion being inserted through the through hole, the column portion comprising a first outer thread spirally surrounding in the vertical direction, and the first inner thread being spirally engaged with the first outer thread; and
a location limiter being sleeved around the column portion and the location limiter being abutted below the cap-shaped cover portion.

20. The radio frequency adjustment structure according to claim 19, further comprising a box base being located below the plate portion, wherein a frequency adjustment cavity is formed between the plate portion and the box base, the smooth rod portion partly extends into the frequency adjustment cavity, and the cap-shaped cover portion is located above the plate portion and surrounding the column portion.
